(19) United States
(12) Patent Application Publication
(10) Pub. No.: US 2026/0023119 A1
(43) Pub. Date: Jan. 22, 2026

(54) TEST SYSTEMS, TEST METHODS AND MEDIUMS FOR ENERGY STORAGE MANAGEMENT SYSTEMS OF PHOTOVOLTAIC CHARGING PILES

(71) Applicant: XCHARGE ENERGY USA INC., Kyle, TX (US)

(72) Inventors: Junshuai WANG, Kyle, TX (US); Rui DING, Kyle, TX (US)

(73) Assignee: XCHARGE ENERGY USA INC., Kyle, TX (US)

(21) Appl. No.: 18/778,911

(22) Filed: Jul. 19, 2024

(51) Int. Cl. G01R 31/367; H02J 7/35

(52) U.S. Cl. CPC G01R 31/367; H02J 7/35

(57) ABSTRACT

A test system and method, and a medium for an energy storage management system of a photovoltaic charging pile are provided. The test system comprises an analog unit, a test switch unit, an acquisition unit, and a processor. The processor is configured to: generate and execute a first acquisition instruction, in response to determining that a first performance feature set does not satisfy a first preset condition: generate a test start instruction and send the test start instruction to the test switch unit when an external load is null, and enable a test circuit composed of the analog unit and an energy storage device to be conducted; in response to determining that the test start instruction is executed and completed, generate a second acquisition instruction and a third acquisition instruction and send the second acquisition instruction and the third acquisition instruction to a battery management system (BMS) and the acquisition unit; determine a second test feature based on test sensing data; in response to determining that a first test feature and a second test feature satisfy a second preset condition, generate first warning information; and in response to determining that the first test feature and the second test feature do not satisfy the second preset condition, generate second warning information and/or generate an accuracy adjustment instruction and send the accuracy adjustment instruction to the BMS.

### TECHNICAL FIELD

The present disclosure relates to the technical field of photovoltaic (PV) charging pile energy storage management, and in particular, to a test system and method, and a medium for an energy storage management system of a photovoltaic charging pile.

### BACKGROUND

An energy storage device and a battery management system of an electric vehicle charging pile have a vital role in the management of electric energy of the photovoltaic charging pile. In the practical application, the performance of the energy storage device and the battery management system may decline over time. In this case, when prompt information indicating, for example, a charging abnormality, is received, it may be caused by the evaluation error resulted from the performance decline of the battery management system, or it may be caused by the performance abnormality of the energy storage device. Accordingly, it is necessary to evaluate the performance of the battery management system and the energy storage device during use to distinguish the cause of the abnormality, thereby making a reverse adjustment to an electric vehicle charging strategy or issuing a warning notification in time.

Therefore, it is desirable to provide a test system and method for an energy storage management system of a photovoltaic charging pile, which can effectively distinguish the abnormalities of the energy storage device and the battery management system, enabling the photovoltaic charging pile to operate efficiently and safely.

### SUMMARY

One or more embodiments of the present disclosure provide a test system for an energy storage management system of a photovoltaic charging pile. The test system may comprise an analog unit, a test switch unit, an acquisition unit, and a processor. The processor may be configured to: generate and execute a first acquisition instruction. The first acquisition instruction may be configured to: obtain a first performance feature set corresponding to a first preset time period by obtaining a plurality of first performance features of an energy storage device of the photovoltaic charging pile during the first preset time period from a battery management system; wherein the plurality of first performance features correspond to a plurality of photovoltaic power generation efficiencies and/or a plurality of electric vehicle charging modes, the plurality of first performance features are determined based on first sensing data, the first sensing data is sensing data of the energy storage device during the first preset time period; and a charging frequency of the photovoltaic charging pile is greater than a preset frequency during the first preset time period; in response to determining that the first performance feature set does not satisfy a first preset condition, generate a test start instruction and send the test start instruction to the test switch unit when an external load is null, the test start instruction being configured to enable a test circuit composed of the analog unit and the energy storage device to be conducted through the test switch unit; in response to determining that the test start instruction is executed and completed, generate a second acquisition instruction and a third acquisition instruction and send the second acquisition instruction and the third acquisition instruction to the battery management system and the acquisition unit, respectively, the second acquisition instruction being configured to obtain a first test feature of the test circuit from the battery management system, and the third acquisition instruction being configured to enable the acquisition unit to acquire test sensing data of the test circuit; wherein the first test feature is determined based on second sensing data, and the second sensing data is sensing data of the energy storage device during a test process of the test circuit; determine a second test feature based on the test sensing data; in response to determining that the first test feature and the second test feature satisfy a second preset condition, generate first warning information, the first warning information including prompt information indicating a potential abnormality of the energy storage device; and in response to determining that the first test feature and the second test feature do not satisfy the second preset condition, generate second warning information and/or generate an accuracy adjustment instruction and send the accuracy adjustment instruction to the battery management system, the second warning information including prompt information indicating a potential abnormality of the battery management system.

One or more embodiments of the present disclosure provide a test method for an energy storage management system of a photovoltaic charging pile, comprising: generating and executing a first acquisition instruction. The first acquisition instruction may be configured to: obtain a first performance feature set corresponding to a first preset time period by obtaining a plurality of first performance features of an energy storage device of the photovoltaic charging pile during the first preset time period from a battery management system; wherein the plurality of first performance features correspond to a plurality of photovoltaic power generation efficiencies and/or a plurality of electric vehicle charging modes, the plurality of first performance features are determined based on first sensing data, the first sensing data is sensing data of the energy storage device during the first preset time period; and a charging frequency of the photovoltaic charging pile is greater than a preset frequency during the first preset time period; in response to determining that the first performance feature set does not satisfy a first preset condition, generate a test start instruction and send the test start instruction to a test switch unit when an external load is null, the test start instruction being configured to enable a test circuit composed of an analog unit and the energy storage device to be conducted through the test switch unit; in response to determining that the test start instruction is executed and completed, generate a second acquisition instruction and a third acquisition instruction and send the second acquisition instruction and the third acquisition instruction to the battery management system and an acquisition unit, respectively, the second acquisition instruction being configured to obtain a first test feature of the test circuit from the battery management system, and the third acquisition instruction being configured to enable the acquisition unit to acquire test sensing data of the test circuit; wherein the first test feature is determined based on second sensing data, and the second sensing data is sensing data of the energy storage device during a test process of the test circuit; determine a second test feature based on the test sensing data; in response to determining that the first test feature and the second test feature satisfy a second preset condition: generate first warning information, the first warning information including prompt information indicating a potential abnormality of the energy storage device; and in response to determining that the first test feature and the second test feature do not satisfy the second preset condition: generate second warning information and/or generate an accuracy adjustment instruction and send the accuracy adjustment instruction to the battery management system, the second warning information including prompt information indicating a potential abnormality of the battery management system.

One or more embodiments of the present disclosure provide a non-transitory computer readable storage medium, comprising computer instructions that, when read by a computer, may direct the computer to implement the test method for the energy storage management system of the photovoltaic charging pile.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering indicates the same structure, wherein:

FIG. 1 is a schematic diagram illustrating an exemplary test system for an energy storage management system of a photovoltaic charging pile according to some embodiments of the present disclosure;

FIG. 2 is a flowchart illustrating an exemplary test method for an energy storage management system of a photovoltaic charging pile according to some embodiments of the present disclosure;

FIG. 3 is a schematic diagram illustrating an exemplary performance feature prediction model according to some embodiments of the present disclosure;

FIG. 4 is a flowchart illustrating an exemplary process of updating a charging control parameter according to some embodiments of the present disclosure; and

FIG. 5 is a flowchart illustrating an exemplary process of determining a preferred parameter adjustment set according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person having ordinary skills in the art to apply the present disclosure to other similar scenarios in accordance with these drawings without creative labor. Unless obviously obtained from the context or the context illustrates otherwise, the same numeral in the drawings refers to the same structure or operation.

It should be understood that “system”, “device”, “unit” and/or “module” as used herein is a method for distinguishing different components, elements, parts, portions or assemblies of different levels. However, the words may be replaced by other expressions if other words can achieve the same purpose.

As indicated in the disclosure and claims, the terms “a”, “an”, and/or “the” are not specific to the singular form and may include the plural form unless the context clearly indicates an exception. Generally speaking, the terms “comprising” and “including” only suggest the inclusion of clearly identified steps and elements, and these steps and elements do not constitute an exclusive list, and the method or device may also contain other steps or elements.

The flowchart is used in the present disclosure to illustrate the operations performed by the system according to the embodiments of the present disclosure. It should be understood that the preceding or following operations are not necessarily performed in the exact order. Instead, various steps may be processed in reverse order or simultaneously. Meanwhile, other operations may be added to these procedures, or a certain step or steps may be removed from these procedures.

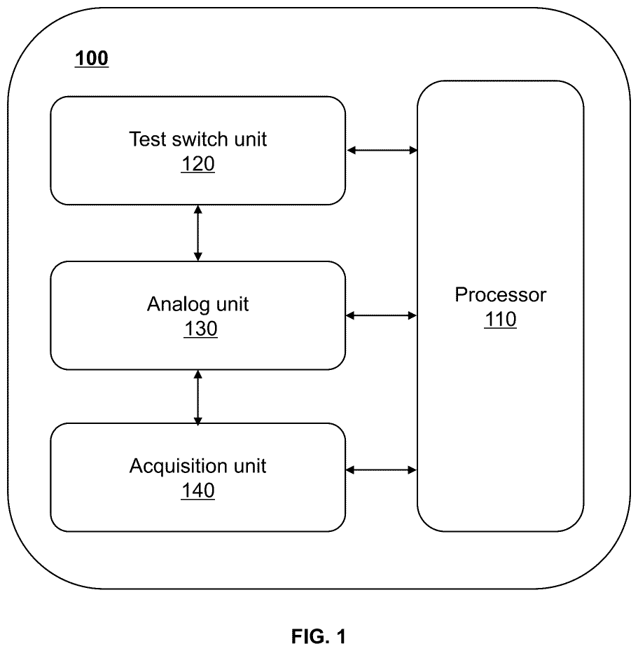

FIG. 1 is a schematic diagram illustrating an exemplary test system for an energy storage management system of a photovoltaic charging pile according to some embodiments of the present disclosure.

As shown in FIG. 1, a test system 100 for an energy storage management system of a photovoltaic charging pile may include a processor 110, a test switch unit 120, an analog unit 130, and an acquisition unit 140.

The processor 110 may be configured to generate and execute a first acquisition instruction.

In some embodiments, the processor 110 may be configured to: in response to determining that a test start instruction is executed and completed, generate a second acquisition instruction and a third acquisition instruction and send the second acquisition instruction and the third acquisition instruction to a battery management system and the acquisition unit 140, respectively.

The battery management system (BMS) refers to a system that manages an energy storage device (e.g., a battery in the energy storage device) in the charging pile, i.e., the battery management system is also referred to as the energy storage management system of the photovoltaic charging pile. In some embodiments, the BMS may be configured to monitor and regulate battery characteristics during charging and discharging processes. The monitored battery characteristics may include a battery type, a voltage, a temperature, a capacity, a state of charge, power consumption, remaining operating time, a charging cycle, or the like.

In some embodiments, the BMS may also be configured to ensure better utilization of remaining energy in a battery. For example, the BMS may protect the battery from deep discharging and over-voltage to avoid a battery load caused by extremely fast charging and extremely high discharging current.

In some embodiments, the BMS may also be configured to provide a battery balancing function in case of a plurality of batteries, so that different battery cells may have the same charging and discharging requirements.

In some embodiments, the processor 110 may be configured to determine a second test feature based on test sensing data; in response to determining that a first test feature and the second test feature obtained from the BMS satisfy a second preset condition, generate first warning information; and in response to determining that the first test feature and the second test feature do not satisfy the second preset condition, generate second warning information and/or generate an accuracy adjustment instruction and send the accuracy adjustment instruction to the BMS.

In some embodiments, the processor 110 may be one of a central processing unit (CPU), a digital signal processor (DSP), an embedded processor, or the like, or any combination thereof.

The test switch unit 120 may be configured to perform the test start instruction, including conducting a test circuit composed of the analog unit 130 and the energy storage device of the photovoltaic charging pile.

In some embodiments, the test switch unit 120 may be implemented based on a switching element in the test circuit to be responsible for connecting or disconnecting the test circuit.

The energy storage device of the photovoltaic charging pile refers to a battery or battery pack within the charging pile that is responsible for storing electric energy.

In some embodiments, the energy storage device refers to a battery pack of energy storage batteries, rechargeable batteries, photovoltaic batteries, or the like. The photovoltaic charging pile may include an energy storage battery, a rechargeable battery, and a photovoltaic battery. The rechargeable battery may be directly connected to an electric vehicle and supplies power to the electric vehicle. The energy storage battery may receive electric energy generated by the photovoltaic battery and electric energy from the grid, and may be responsible for supplying power to the rechargeable battery. The photovoltaic battery may receive light and generate electric energy.

In some embodiments, the energy storage battery may also have the functions of the rechargeable battery and the photovoltaic battery, i.e., the functions of both the rechargeable battery and the photovoltaic battery may be combined into the energy storage battery (the battery pack). The analog unit 130 may serve as an analog structure for generating a power demand in a test. For example, the analog unit 130 may be one or more batteries.

When a first performance feature set does not satisfy a first preset condition and an external load is null, the test circuit composed of the analog unit 130 and the energy storage device may be conducted. The test circuit refers to an electric path from the analog unit 130 to the energy storage device. When the test circuit is conducted, the energy storage device may supply power to the analog unit 130. After the test is completed, power of the analog unit 130 may flow back to the energy storage device to reduce the waste of power during the test.

In some embodiments, the processor 110 may determine, based on the test circuit, whether an abnormality exists in the energy storage device or the BMS. When testing is performed based on the test circuit, the energy storage device may deliver electric energy to the analog unit 130. In this process, the BMS and the acquisition unit 140 may respectively acquire data during the testing process to determine whether the BMS has the abnormality.

The acquisition unit 140 may be configured to perform a third acquisition instruction, e.g., to acquire the test sensing data for the test circuit. In some embodiments, the acquisition unit 140 may be implemented based on a sensing device.

In some embodiments, the processor 110 may be connected with various components (e.g., the test switch unit 120, the analog unit 130, and the acquisition unit 140, or the like) of the test system 100 and/or other components other than the test system 100. In some embodiments, one or more components of the test system 100 may be connected with each other through the processor 110.

For example, the test switch unit 120 may be connected with the analog unit 130 through the test start instruction sent by the processor 110, and the analog unit 130 may be connected with the acquisition unit 140 for data exchange and communication, etc.

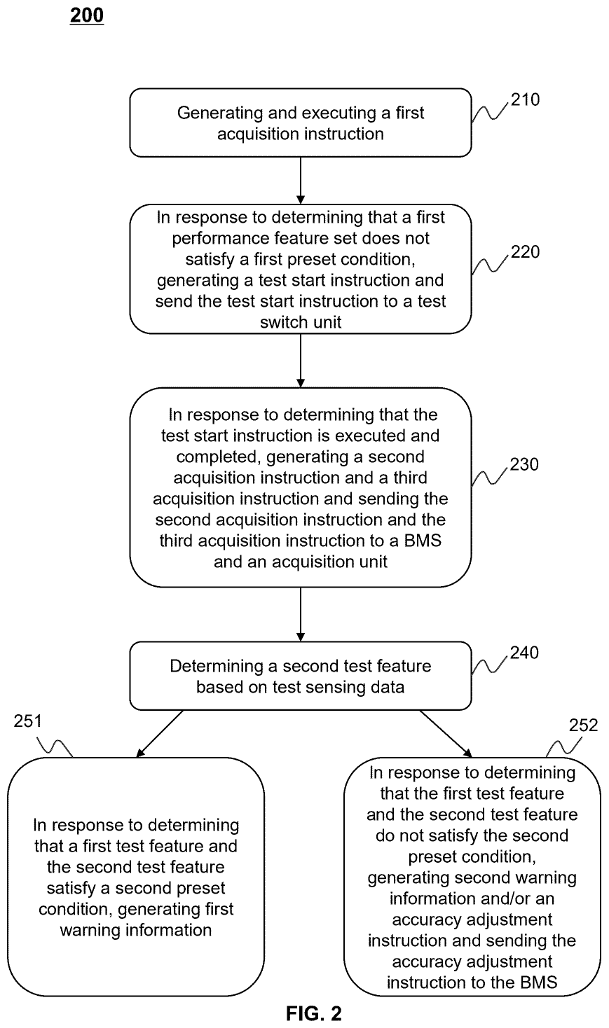

More descriptions regarding the processor 110, the test switch unit 120, the analog unit 130, and the acquisition unit 140 may be found in the related descriptions of FIG. 2-FIG. 5.

FIG. 2 is a flowchart illustrating an exemplary test method for an energy storage management system of a photovoltaic charging pile according to some embodiments of the present disclosure. As shown in FIG. 2, a process 200 may include the following operations. In some embodiments, the process 200 may be performed by the processor 110.

In 210, the processor 110 may be configured to generate and execute a first acquisition instruction.

The first acquisition instruction refers to an instruction for obtaining a first performance feature set by obtaining a plurality of first performance features. In some embodiments, the first acquisition instruction may be configured to obtain the first performance feature set corresponding to a first preset time period by obtaining a plurality of first performance features of an energy storage device of the photovoltaic charging pile during the first preset time period from a BMS.

The first preset time period refers to a period of time before current time. For example, the first preset time period may be one day prior to the current time. In some embodiments, the first preset time period may be selected with constraints. For example, the constraints may include that a charging frequency of the photovoltaic charging pile is greater than a preset frequency during the first preset time period. The preset frequency may be preset based on prior experience.

Merely by way of example, the charging frequency within each of a plurality of time periods may be calculated, and any time period in which the charging frequency is greater than the preset frequency may be determined as the first preset time period. In this way, a duration of the first preset time period may be adaptive, thereby ensuring sufficient times of charging during the first preset time period to obtain more first performance features, and ensuring the data diversity of the first performance feature set.

The plurality of first performance features refer to features related to the performance of the energy storage device during the first preset time period. The first performance feature set is a collection of plurality of first performance features.

In some embodiments, the plurality of first performance features may be determined by the BMS based on first sensing data. More descriptions regarding the BMS may be found in the related descriptions of FIG. 1.

The first sensing data refers to sensing data of the energy storage device during the first preset time period. The first sensing data may include temperature sensing data, humidity sensing data, current sensing data, voltage sensing data, or the like. The first sensing data may be obtained based on sensors within the BMS.

In some embodiments, the plurality of first performance features may correspond to a plurality of photovoltaic power generation efficiencies and/or a plurality of electric vehicle charging modes. That is, one first performance feature may correspond to an average temperature and an average humidity of the energy storage device, an average discharging rate of the energy storage device, an average charging rate of an electric vehicle, or the like, under a preset photovoltaic power generation efficiency and a preset electric vehicle charging mode.

In some embodiments, the BMS may obtain the average temperature and the average humidity of the energy storage device of the photovoltaic charging pile by calculating based on the first sensing data.

In some embodiments, the BMS may calculate the average discharging rate of the energy storage device based on a rate of change of a state of charge of a battery pack.

The state of charge of the battery pack refers to a ratio of a remaining capacity of the battery pack in the energy storage device of the photovoltaic charging pile to a rated capacity. The state of charge of the battery pack may be determined based on the BMS.

In some embodiments, the BMS may communicate with the electric vehicle management system to obtain an average rate of increase in battery charge of the electric vehicle and determine the average rate of increase as the average charging rate of the electric vehicle.

In some embodiments, the BMS may determine the electric vehicle charging mode based on a rated charging power of the electric vehicle. For example, the BMS may divide the rated charging power of the electric vehicle into a plurality of power intervals. Each of the plurality of power intervals may correspond to one electric vehicle charging mode. The electric vehicle charging mode may be determined based on a power interval in which the rated charging power of the electric vehicle is located.

For example, assuming that a length of each of the plurality of power intervals is 5 KW, (0-5 KW) may correspond to a charging mode 1, [5-10 KW) may correspond to charging mode 2, and so forth.

In some embodiments, the BMS may calculate the photovoltaic power generation efficiency based on an amount of irradiation received by the photovoltaic charging pile, and an amount of power generated by the photovoltaic charging pile. The amount of irradiation received by the photovoltaic charging pile, and the amount of power generated by the photovoltaic charging pile may be obtained based on the sensors within the BMS.

In some embodiments, assuming that during a certain charging process, the photovoltaic power generation efficiency is A1, the electric vehicle charging mode is M1, the average temperature of the energy storage device of the photovoltaic charging pile is T1, the average humidity is H1, the average discharging rate of the energy storage device of the photovoltaic charging pile is C1, and the average charging rate of the electric vehicle is P1, the first performance feature (corresponding to the charging process) may be expressed as [A1, M1] (T1, H1, C1, P1).

The first performance feature set may be obtained based on the plurality of first performance features corresponding to the plurality of photovoltaic power generation efficiencies and/or the plurality of electric vehicle charging modes.

In 220, in response to determining that the first performance feature set does not satisfy a first preset condition, the processor 110 may be configured to generate a test start instruction and send the test start instruction to a test switch unit.

The first preset condition refers to a condition for determining whether to perform a test. For example, the first preset condition may be that at least one of the average temperature, the average humidity, the average discharging rate, and the average charging rate of the plurality of first performance features in the first performance feature set does not satisfy a preset first threshold condition.

The processor 110 may determine the first threshold condition based on a first performance feature corresponding to a historical actual fault of the photovoltaic charging pile, and then determine the first preset condition. Merely by way of example, the first threshold condition may include that the average temperature is greater than a preset temperature threshold, the average discharging rate is less than a preset discharging rate, or the like. The preset temperature threshold and the preset discharging rate may be preset based on experience.

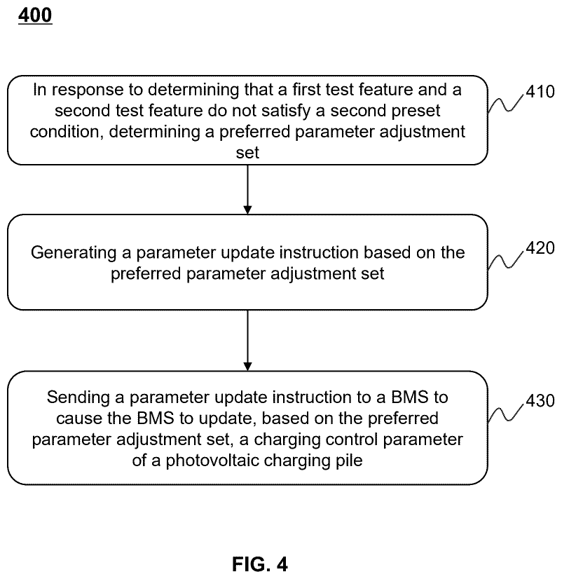

In some embodiments, the first preset condition may also be that a performance evaluation value of at least one of the plurality of first performance features in the first performance feature set does not satisfy a preset second threshold condition. Merely by way of example, the second threshold condition may be that the performance evaluation value of the first performance feature is less than a preset performance evaluation value threshold. The preset performance evaluation value threshold may be preset based on experience. The second threshold condition may be determined based on historical experience. More descriptions regarding the performance evaluation value may be found in the related descriptions of FIG. 4.

In some embodiments, when the first performance feature set does not satisfy the first preset condition, the performance of a current photovoltaic charging system may not meet expectations, and the photovoltaic charging system may have an abnormality. For example, the BMS or the energy storage device of the photovoltaic charging pile may have an abnormality.

In some embodiments, the processor 110 may also determine, based on the first performance feature set, a second performance feature set corresponding to a second preset time period.

The second preset time period refers to a future period of time of the current time. The second preset time period may be preset based on experience. For example, the second preset time period may be one day in the future, etc.

The second performance feature set is a collection of a plurality of second performance features. The plurality of second performance features refer to features related to the performance of the energy storage device during the second preset time period.

In some embodiments, the first preset condition may further include that a count of target performance features is greater than a preset number threshold. The preset number threshold may be determined based on historical experience.

The target performance features may include first performance features of which performance evaluation values are less than a first performance threshold, and second performance features of which performance evaluation values are less than a second performance threshold. More descriptions regarding determining the performance evaluation values may be found in the related descriptions of FIG. 4. The first performance threshold may be determined based on historical experience.

In some embodiments, the second performance threshold may be negatively correlated with a count of the plurality of first performance features in the first performance feature set. The smaller the count of the plurality of first performance features, the larger the second performance threshold.

When the count of the plurality of first performance features is small, the accuracy of the second performance feature set determined based on the first performance feature set may be low. To this end, the second performance threshold may be increased to avoid misjudgment.

In some embodiments, the plurality of second performance features may correspond to a plurality of photovoltaic power generation efficiencies and/or a plurality of electric vehicle charging modes. That is, one second performance feature may correspond to an average temperature and an average humidity of the energy storage device, an average discharging rate of the energy storage device, an average charging rate of an electric vehicle, or the like, under a preset photovoltaic power generation efficiency and a preset electric vehicle charging mode. The electric vehicle charging mode may be categorized into fast charging and slow charging.

The processor 110 may determine the second performance feature set based on the first performance feature set in various ways. For example, in some embodiments, the processor 110 may fit various data in the first performance feature set to obtain a fitted change curve of the various data with the photovoltaic power generation efficiency and the electric vehicle charging mode. A plurality of second performance features may be obtained through a plurality of calculations based on the plurality of preset photovoltaic power generation efficiencies and the electric vehicle charging modes corresponding to the plurality of second performance features in combination with the fitted change curve to form the second performance feature set.

The fitting may include but is not limited to at least one of least squares fitting, polynomial fitting, or the like, or any combination thereof.

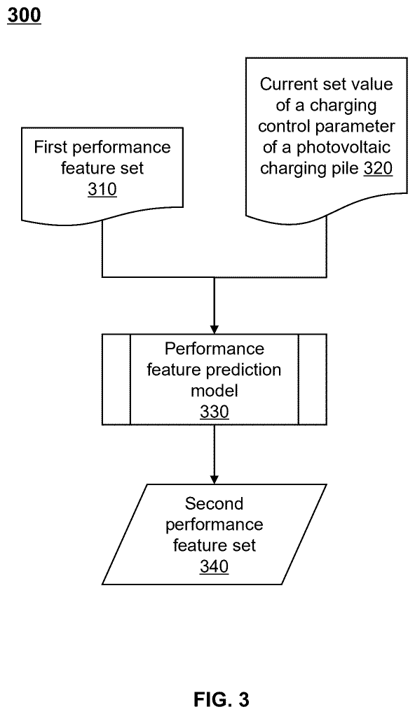

In some embodiments, the processor 110 may also determine the second performance feature set based on a performance feature prediction model. More descriptions regarding the performance feature prediction model may be found in the related descriptions of FIG. 3.

In some embodiments of the present disclosure, the second performance feature set may be predicted, and it may be determined whether the BMS has the abnormality or a hidden danger based on the second performance feature set, so that the determination result is more accurate.

The test start instruction refers to an instruction for controlling startup of the test circuit. In some embodiments, the test start instruction may be configured to enable the test circuit composed of the analog unit 130 and the energy storage device to be conducted through the test switch unit 120.

In some embodiments, when the first performance feature set does not satisfy the first preset condition and the external load is null, the processor 110 may generate the test start instruction and send the test start instruction to the test switch unit 120 to perform the test. The external load being null means that the photovoltaic charging pile does not charge the electric vehicle at present.

In 230, in response to determining that the test start instruction is executed and completed, the processor 110 may be configured to generate a second acquisition instruction and a third acquisition instruction and send the second acquisition instruction and the third acquisition instruction to a BMS and an acquisition unit.

The second acquisition instruction may be configured to acquire a first test feature. In some embodiments, the second acquisition instruction may be configured to obtain the first test feature of the test circuit from the BMS.

The third acquisition instruction may be configured to acquire test sensing data of the test circuit. In some embodiments, the third acquisition instruction may be configured to enable the acquisition unit 140 to acquire the test sensing data of the test circuit.

The test sensing data refers to sensing data acquired by the acquisition unit 140 during the testing process. The test sensing data may include temperature sensing data, humidity sensing data, current sensing data, voltage sensing data, or the like, of the energy storage device.

The first test feature refers to a feature determined by the BMS that is related to the testing process of the test circuit. The first test feature may include an average temperature, an average humidity of the energy storage device of the photovoltaic charging pile, a discharging rate of the energy storage device of the photovoltaic charging pile, a charging rate of the electric vehicle, etc. In some embodiments, the BMS may determine the first test feature based on the second sensing data. The first test feature may be determined in a similar manner as the first performance features as described above.

The second sensing data refers to sensing data of the energy storage device acquired based on the sensors within the BMS during the testing process. The second sensing data may include temperature sensing data, humidity sensing data, current sensing data, voltage sensing data, or the like, of the energy storage device.

In 240, the processor 110 may be configured to determine a second test feature based on test sensing data.

The second test feature refers to a feature determined by the processor 110 that is related to the testing process of the test circuit. The second test feature may include an average temperature, an average humidity of the energy storage device of the photovoltaic charging pile, a discharging rate of the energy storage device of the photovoltaic charging pile, a charging rate of the electric vehicle, etc. In some embodiments, the processor 110 may determine the second test feature based on the test sensing data. The second test feature may be determined in a similar manner as the first performance features as described above.

In 251, in response to determining that a first test feature and the second test feature satisfy a second preset condition, the processor 110 may be configured to generate first warning information.

The second preset condition may be configured to determine what kind of warning information is generated. For example, the second preset condition may be that the first test feature is different from the second test feature, or that a difference between the first test feature and the second test feature is greater than a preset difference range. The preset difference range may be set based on experience.

In some embodiments, when the first test feature and the second test feature satisfy the second preset condition, the BMS may be normal, and the energy storage device of the photovoltaic charging pile may have a potential abnormality.

The first warning information may be configured to provide warning of the potential abnormality in the energy storage device. The first warning information may be displayed in various ways, such as a text, sound, light, etc.

In 252, in response to determining that the first test feature and the second test feature do not satisfy the second preset condition, the processor 110 may be configured to generate second warning information and/or an accuracy adjustment instruction and send the accuracy adjustment instruction to the BMS.

In some embodiments, when the first test feature and the second test feature do not satisfy the second preset condition, the BMS may have the potential abnormality.

The second warning information may be configured to provide warning of the potential abnormality in the BMS. The second warning information may be displayed in various ways, such as a text, sound, light, etc., different from the first warning information.

In some embodiments, when the first test feature and the second test feature do not satisfy the second preset condition, the processor 110 may also generate an accuracy adjustment instruction and send the accuracy adjustment instruction to the BMS.

The accuracy adjustment instruction may be configured to adjust a data acquisition accuracy of the BMS and an estimation accuracy of a state of charge of a battery pack. The data acquisition accuracy refers to a data acquisition accuracy of the sensors within the BMS. The estimation accuracy of the state of charge of the battery pack may be related to an estimation algorithm of the state of charge of the battery pack stored in the BMS. The BMS may adjust the data acquisition accuracy by modifying parameters of the internal sensors, and adjust the estimation accuracy of the state of charge of the battery pack by selecting different estimation algorithms of the state of charge of the battery pack. For example, the estimation algorithm of the state of charge of the battery pack may include, but is not limited to, at least one of an integral method, a Kalman filtering method, an equivalent circuit method, a neural network-based method, or the like.

In some embodiments of the present disclosure, it may be determined whether the system has the abnormality based on the first performance feature and the second performance feature, so that the determination result is more accurate, and losses caused by misjudgment and failure to perform maintenance in time can be avoided. After the test is performed, it may be determined which abnormality occurs based on the first test feature and the second test feature, and the corresponding warning may be provided, so that the maintenance personnel can take measures in time to avoid damage to the system.

It should be noted that the description of the process 200 above is intended to be exemplary and illustrative only and does not limit the scope of the present disclosure. For a person skilled in the art, various corrections and changes may be made to the process 200 under the guidance of the present disclosure. The corrections and changes, however, still fall within the scope of the present disclosure.

FIG. 3 is a schematic diagram illustrating an exemplary performance feature prediction model according to some embodiments of the present disclosure.

As shown in FIG. 3, in some embodiments, the processor 110 may determine a second performance feature set 340 by processing a first performance feature set 310 through a performance feature prediction model 330. In some embodiments, the performance feature prediction model 330 may be a machine learning model. For example, the performance feature prediction model 330 may be a Long Short Term Memory (LSTM) neural network model. More descriptions regarding the first performance feature set and the second performance feature set may be found in the related descriptions of FIG. 2.

An input of the performance feature prediction model 330 may include the first performance feature set 310, and an output of the performance feature prediction model 330 may include the second performance feature set 340.

In some embodiments, the performance feature prediction model may be obtained by training based on a plurality of training samples and a plurality of labels corresponding to the plurality of training samples. For example, the processor 110 may input the plurality of training samples into an initial performance feature prediction model, construct a loss function based on outputs of the initial performance feature model and the plurality of labels, and iteratively update (a magnitude of update of the model parameters at each iteration update may be determined based on learning rates corresponding to the samples used in current iteration) parameters of the initial performance feature prediction model based on a value of the loss function by methods such as a gradient descent method, etc. When the value of the loss function satisfies an iteration completion condition, the training may be completed, and a trained performance feature prediction model may be obtained. The iteration completion condition may include that the loss function converges, a number of iterations reaches a threshold, or the like.

In some embodiments, the plurality of training samples may include historical first performance feature sets in historical data, and the plurality of labels may include historical second performance feature sets corresponding to the historical first performance feature sets. For a set of training samples and labels, the historical first performance feature set refers to an actual performance feature set during a time period prior to certain historical time, and the historical second performance feature set refers to an actual performance feature set during a time period after the same historical time. The processor 110 may compute to obtain the training samples and the labels by the following operations.

Operation 1, the processor 110 may obtain a large amount of historical data, the historical data including performance features of the photovoltaic charging pile when the battery management system is normal and the photovoltaic charging pile supplies power to the outside at/during a large amount of historical times or time periods.

Operation 2, the processor 110 may divide the historical data according to a preset duration to obtain a plurality sets of historical sub-data, each set of historical sub-data corresponding to a historical time period, and the preset duration being set based on experience.

Operation 3, for each set of historical sub-data, the processor 110 may randomly generate a segmentation time point within a historical time period corresponding to the set of historical sub-data, and segment the historical sub-data by the segmentation time point with data in the set of historical sub-data before the segmentation time point as a set of training samples, and the data in the set of historical sub-data after the segmentation time point as labels corresponding to the set of training samples.

Operation 4, the processor 110 may repeat the operation 3 to obtain the plurality sets of training samples and the labels corresponding to the plurality sets of training samples.

In some embodiments, the plurality of training samples may correspond to a plurality of learning rates, i.e., each of the plurality of training samples may correspond to one learning rate (also referred to as a learning rate corresponding to the training sample). The learning rate refers to a rate at which the model updates a weight parameter based on the training samples during training.

In some embodiments, the learning rate may be related to a ratio of a sample length of each of the plurality of training samples to a label length of each of the plurality of training samples. The greater the ratio of the sample length to the label length, the greater the learning rate of the training sample.

The sample length refers to a duration of a time period corresponding to the training sample, and the label length refers to a duration of a time period corresponding to the label.

The greater the ratio of the sample length to the label length, the greater the proportion of data used for feature extraction, which generally indicates stronger descriptive capabilities of the data for features and contributes to training a more accurate model.

In some embodiments, the input of the performance feature prediction model 330 may also include a current set value 320 of a charging control parameter of the photovoltaic charging pile.

More descriptions regarding the charging control parameter of the photovoltaic charging pile may be found in the related descriptions of FIG. 4.

In some embodiments, when the input of the performance feature prediction model 330 includes the current set value 320 of the charging control parameter of the photovoltaic charging pile, the training samples may be historical set values of different charging control parameters of the photovoltaic charging pile, and historical first performance feature sets under the different historical set values. The labels corresponding to the training samples may be historical second performance feature sets corresponding to the historical first performance feature sets under the different historical set values.

In some embodiments of the present disclosure, the second performance feature set may be determined by taking the current set value of the charging control parameter of the photovoltaic charging pile as the input, avoiding the influence of a change in the charging control parameter on an output result, thereby making the obtained second performance feature set more accurate.

In some embodiments of the present disclosure, the second performance feature set may be determined through the performance feature prediction model, making the output result more accurate. In the subsequent determination of whether testing is needed based on the second performance feature set, the determination result may be more accurate, so that the potential abnormality in the system can be discovered and corresponding measures can be implemented in time, thereby ensuring the normal use of the photovoltaic charging pile.

FIG. 4 is a flowchart illustrating an exemplary process of updating a charging control parameter according to some embodiments of the present disclosure. As shown in FIG. 4, a process 400 may include the following operations. In some embodiments, the process 400 may be performed by the processor 110.

In some embodiments, a second preset condition may include that a difference between a first test feature and a second test feature is less than a preset difference threshold. The preset difference threshold may be set based on historical experience.

The difference between the first test feature and the second test feature refers to a difference between a performance evaluation value of the first test feature and a performance evaluation value of the second test feature.

In some embodiments, the processor 110 may also determine the preset difference threshold based on a performance evaluation value of a first performance feature set and a performance evaluation value of a second performance feature set.

A performance feature (e.g., a first performance feature or a second performance feature) or a test feature (e.g., the first test feature or the second test feature) may collectively be referred to as an evaluation feature. A performance evaluation value of the evaluation feature is configured to reflect the performance of a photovoltaic charging pile for a scenario (e.g., a photovoltaic power generation efficiency corresponding to the evaluation feature and/or a plurality of electric vehicle charging modes) corresponding to the evaluation feature.

In some embodiments, the processor 110 may determine the performance evaluation value of the evaluation feature based on a sensing data feature corresponding to the evaluation feature. The sensing data feature may include, e.g., an average temperature, an average humidity, an average discharging rate of an energy storage device, and an average charging rate of an electric vehicle in the scenario corresponding to the evaluation feature. More descriptions may be found in the related descriptions of FIG. 2.

For example, assuming that during a certain charging process, a photovoltaic power generation efficiency of the photovoltaic charging pile is A1, an electric vehicle charging mode is M1, the average temperature of the energy storage device of the photovoltaic charging pile is T1, the average humidity is H1, the average discharging rate of the energy storage device of the photovoltaic charging pile is C1, and the average charging rate of the electric vehicle is P1, a corresponding evaluation feature may be constructed as [A1, M1] (T1, H1, C1, and P1). Then the processor 110 may calculate the performance evaluation value of the evaluation feature by the following equation (1):

$$D = k 1 \times \vert T 1 - ST \vert + k 2 \times \vert H 1 - SH \vert + k 3 \times \vert C 1 - SC \vert + k 4 \times \vert P 1 - SP \vert \qquad ( 1 )$$

wherein ST denotes a standard average temperature of the energy storage device based on the photovoltaic power generation efficiency and the electric vehicle charging mode [A1, M1] corresponding to the evaluation feature, SH denotes a standard average humidity of the energy storage device the based on the photovoltaic power generation efficiency and the electric vehicle charging mode [A1, M1] corresponding to the evaluation feature, SC denotes a standard discharging rate of the energy storage device based on the photovoltaic power generation efficiency and the electric vehicle charging mode [A1, M1] corresponding to the evaluation feature, SP denotes a standard charging rate of the electric vehicle based on the photovoltaic power generation efficiency and the electric vehicle charging mode [A1, M1] corresponding to this evaluation feature, and ST, SH, SC, and SP may be obtained based on historical data. k1, k2, k3, k4 denote corresponding weights, which may all be ¼.

In some embodiments, k1, k2, k3, k4 may also be determined based on the photovoltaic power generation efficiency and the electric vehicle charging mode corresponding to the evaluation feature. For example, when the photovoltaic power generation efficiency is high, it is more important to consider heat generation of the energy storage device, and k1 may be increased; or as another example, when the charging mode is fast charging and charging power is high, it is more important to consider the charging efficiency, and k3 and k4 may be increased.

Based on the method described above, the processor 110 may determine the performance evaluation value of the first test feature and the performance evaluation value of the second test feature, respectively, and then determine the difference between the performance evaluation value of the first test feature and the performance evaluation value of the second test feature to determine whether the first test feature and the second test feature satisfy a second preset condition.

A performance evaluation value of a performance feature set may reflect an average of the performance of the photovoltaic charging pile corresponding to a plurality of performance features included in the performance feature set. The performance of the photovoltaic charging pile may include a charging efficiency of the photovoltaic charging pile, a safety of the photovoltaic charging pile, or the like.

In some embodiments, the processor 110 may calculate a performance evaluation value of each of the plurality of performance features in the performance feature set, and take an average value of the performance evaluation values of all the performance features as the performance evaluation value of the performance feature set.

Based on the above manner, the processor 110 may determine the performance evaluation value of the second performance feature set and the performance evaluation value of the first performance feature set, respectively, and then determine the preset difference threshold in the second preset condition.

In some embodiments, the preset difference threshold in the second preset condition may be positively correlated with the difference between the performance evaluation value of the first performance feature set and the performance evaluation value of the second performance feature set. The greater the difference between the performance evaluation value of the first performance feature set determined based on a BMS and the performance evaluation value of the second performance feature set determined based on the processor 110, the greater the possibility that the current photovoltaic charging pile has a hidden problem. In this case, the preset difference threshold may be increased to improve the accuracy of determining a potential abnormality in the energy storage device of the photovoltaic charging pile.

In 410, in response to determining that a first test feature and a second test feature do not satisfy a second preset condition, the processor 110 may be configured to determine a preferred parameter adjustment set.

The preferred parameter adjustment set refers to a collection of a plurality of preferred parameter adjustment quantities. The plurality of preferred parameter adjustment quantities refer to related parameters preferentially selected to be adjusted for a charging control parameter. Each of the plurality of preferred parameter adjustment quantities may correspond to one charging control parameter.

The charging control parameter refers to a parameter related to charging control of the electric vehicle. The charging control parameter may be related to a control mode during a charging process of the electric vehicle.

In some embodiments, the control mode during the charging process of the electric vehicle may include a three-stage charging control mode, a four-stage charging control mode, and so on, which may be managed and controlled based on the BMS.

The three-stage charging control mode may divide the charging process into the following three stages.

A constant current stage: constant current charging may be performed at a first set current, and when a battery voltage rises to a first set voltage, constant voltage charging may be switched on.

A constant voltage stage: a charging voltage may be maintained at a second set voltage. In this case, a charging current may gradually decrease.

An end stage: charging may be ended when the current drops to a second set current.

The four-stage charging control mode may divide the charging process into the following four stages.

Stage 1: trickle charging may be enabled when the battery voltage is below the first set voltage, a trickle charging current being 1/N of the constant current charging current.

Stage 2: when the battery voltage rises above a trickle charging threshold, the charging current may be increased for constant current charging, the current of constant current charging being the first set current.

Stage 3: when the battery voltage rises to the second set voltage, the constant current charging may be ended and the constant voltage charging stage may begin, the voltage of constant voltage charging being a third set voltage.

Stage 4: a charging current of the constant voltage charging stage may be monitored, and charging may be ended when the charging current is less than the second set current; or the charging process may be ended after a continuous charging of T hours from the start of the constant voltage charging stage.

In the above charging mode, parameters such as the first set current, the second set current, the first set voltage, the second set voltage, the third set voltage, an N value, a T value, the trickle charging threshold, etc. are collectively referred to as the charging control parameters. Correspondingly, the preferred parameter adjustment quantities may include an adjustment quantity of the first set current, an adjustment quantity of the second set current, an adjustment quantity of the first set voltage, an adjustment quantity of the second set voltage, an adjustment quantity of the third set voltage, an adjustment quantity of the N value, an adjustment quantity of the T value, an adjustment quantity of the trickle charging threshold, etc.

In some embodiments, the processor 110 may determine the preferred parameter adjustment set based on historical experience. For example, the processor 110 may obtain the preferred parameter adjustment set by calculating a difference between a charging control parameter of a photovoltaic charging pile with better operation in historical data and a charging control parameter of the current photovoltaic charging pile. The better operation may include, but is not limited to, a low system fault rate, high system performance, etc.

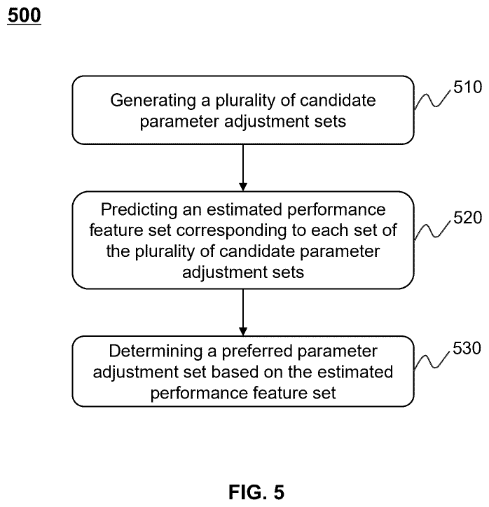

In some embodiments, the processor 110 may also determine the preferred parameter adjustment set based on a plurality of candidate parameter adjustment sets. More descriptions may be found in the related descriptions of FIG. 5.

In 420, the processor 110 may be configured to generate a parameter update instruction based on the preferred parameter adjustment set.

The parameter update instruction may be configured to control the BMS to update the charging control parameter.

In 430, the processor 110 may send a parameter update instruction to a BMS to cause the BMS to update, based on the preferred parameter adjustment set, a charging control parameter of a photovoltaic charging pile.

In some embodiments, the processor 110 may generate the parameter update instruction and send the parameter update instruction to the BMS. The BMS may increase the preferred parameter adjustment quantities based on the current charging control parameter to obtain an updated charging control parameter.

In some embodiments of the present disclosure, when the charging control parameter is set unreasonably, the preferred parameter adjustment set may be determined, and the parameter update instruction may be generated and sent to the BSM. The BSM may update the charging control parameter based on the preferred parameter adjustment set. The updated charging control parameter may be more reasonable, thereby improving the performance of the system, and ensuring the normal operation of the system.

FIG. 5 is a flowchart illustrating an exemplary process of determining a preferred parameter adjustment set according to some embodiments of the present disclosure. As shown in FIG. 5, a process 500 may include the following operations. In some embodiments, the process 500 may be performed by the processor 110.

In 510, the process 500 may be configured to generate a plurality of candidate parameter adjustment sets.

The plurality of candidate parameter adjustment sets refer to parameter adjustment sets that may be determined as the preferred parameter adjustment set. More descriptions regarding the preferred parameter adjustment set may be found in the related descriptions of FIG. 4.

In some embodiments, the processor 110 may randomly generate the plurality of candidate parameter adjustment sets.

In some embodiments, the processor 110 may also determine a set generation volume based on a count of a plurality of first performance features in a first performance feature set; and generate the plurality of candidate parameter adjustment sets based on the set generation volume. More descriptions regarding the first performance feature set and the plurality of first performance features may be found in the related descriptions of FIG. 2.

The set generation volume refers to a count of the generated plurality of candidate parameter adjustment sets. In some embodiments, the set generation volume may be negatively correlated with the count of the plurality of first performance features in the first performance feature set. The smaller the count of the plurality of first performance features, the larger the set generation volume.

The smaller the count of the plurality of first performance features, the smaller the initial amount of data. By increasing the set generation volume, a greater count of candidate parameter adjustment sets may be generated, which may improve the possibility of finding a more suitable preferred parameter adjustment set from the plurality of candidate parameter adjustment sets.

In 520, the processor 110 may be configured to predict an estimated performance feature set corresponding to each set of the plurality of candidate parameter adjustment sets.

The estimated performance feature set refers to an estimated performance feature set corresponding to each of the plurality of candidate parameter adjustment sets. The estimated performance feature set may include an average temperature and an average humidity of an energy storage device of a photovoltaic charging pile, an average discharging rate of the energy storage device of the photovoltaic charging pile, an average charging rates of an electric vehicle, etc., based on a plurality of preset photovoltaic power generation efficiencies and a plurality of preset electric vehicle charging modes.

In some embodiments, the processor 110 may determine the estimated performance feature set based on the plurality of candidate parameter adjustment sets by fitting historical data, querying a vector database, or the like. The manner of determining the estimated performance feature set may be similar to the manner of determining the second performance feature set. More descriptions may be found in the related descriptions of FIG. 2.

In some embodiments, the processor 110 may predict a plurality of estimated performance feature sets corresponding to the plurality of candidate parameter adjustment sets by processing the first performance feature set, and an update value of the charging control parameter of the photovoltaic charging pile through a performance feature prediction model.

In some embodiments, a process of predicting the estimated performance feature set corresponding to each set of the plurality of candidate parameter adjustment sets by processing the first performance feature set and the update value of the charging control parameter of the photovoltaic charging pile based on the performance feature prediction model by the processor 110 may be the same as a process of predicting the second performance feature set by processing the first performance feature set and the current set value of the charging control parameter of the photovoltaic charging pile based on the performance feature prediction model. The update value of the charging control parameter of the photovoltaic charging pile input into the performance feature prediction model may represent the current set value of the charging control parameter of the photovoltaic charging pile during the prediction process as above. Accordingly, the estimated performance feature set corresponding to the each set of the plurality of candidate parameter adjustment sets outputted by the performance feature prediction model may represent the second performance feature set obtained during the prediction process as above. More descriptions regarding the performance feature prediction model may be found in the related descriptions of FIG. 3.

In some embodiments, the processor 110 may increase an adjustment quantity of the charging control parameter corresponding to each set of the plurality of candidate parameter adjustment sets based on the current set value of the charging control parameter of the photovoltaic charging pile to obtain the updated value of the charging control parameter.

In some embodiments of the present disclosure, the estimated performance feature set corresponding to each set of the plurality of candidate parameter adjustment sets may be obtained through the performance feature prediction model, so that the estimated performance feature set may be more accurate, thereby selecting a more suitable preferred parameter adjustment set.

In 530, the processor 110 may be configured to determine a preferred parameter adjustment set based on the estimated performance feature set.

In some embodiments, the processor 110 may calculate a performance evaluation value of each estimated performance feature set.

The processor 110 may determine a candidate parameter adjustment set corresponding to an estimated performance feature set with a highest performance evaluation value as the preferred parameter adjustment set. More descriptions regarding calculating the performance evaluation value may be found in the related descriptions of FIG. 4.

In some embodiments of the present disclosure, the preferred parameter adjustment set may be determined based on the plurality of candidate parameter adjustment sets, and the candidate parameter adjustment set corresponding to the estimated performance feature set with the highest performance evaluation value may be selected. The charging control parameter may be adjusted based on the preferred parameter adjustment set, thereby improving the performance of the photovoltaic charging pile to the greatest extent, and reducing the failure rate.

It should be noted that the above descriptions of the process 500 are merely provided for the purposes of illustration, and not intended to limit the scope of the present disclosure. For persons having ordinary skills in the art, multiple variations and modifications may be made to the process 500 under the teachings of the present disclosure. However, those variations and modifications still fall within the scope of the present disclosure.

The basic concept has been described above. Obviously, for those skilled in the art, the above detailed disclosure is only an example, and does not constitute a limitation to the present disclosure. Although not expressly stated here, those skilled in the art may make various modifications, improvements and corrections to the present disclosure. Such modifications, improvements and corrections are suggested in this disclosure, so such modifications, improvements and corrections still belong to the spirit and scope of the exemplary embodiments of the present disclosure.

Meanwhile, the present disclosure uses specific words to describe the embodiments of the present disclosure. For example, “one embodiment”, “an embodiment”, and/or “some embodiments” refer to a certain feature, structure or characteristic related to at least one embodiment of the present disclosure. Therefore, it should be emphasized and noted that references to “one embodiment” or “an embodiment” or “an alternative embodiment” two or more times in different places in the present disclosure do not necessarily refer to the same embodiment. In addition, certain features, structures, or characteristics in one or more embodiments of the present disclosure may be properly combined.

In addition, unless clearly stated in the claims, the sequence of processing elements and sequences described in the present disclosure, the use of counts and letters, or the use of other names are not used to limit the sequence of processes and methods in the present disclosure. While the foregoing disclosure has discussed by way of various examples some embodiments of the invention that are presently believed to be useful, it should be understood that such detail is for illustrative purposes only and that the appended claims are not limited to the disclosed embodiments, but rather, the claims are intended to cover all modifications and equivalent combinations that fall within the spirit and scope of the embodiments of the present disclosure. For example, although the implementation of various components described above may be embodied in a hardware device, it may also be implemented as a software only solution, e.g., an installation on an existing server or mobile device.

In the same way, it should be noted that in order to simplify the expression disclosed in this disclosure and help the understanding of one or more embodiments of the invention, in the foregoing description of the embodiments of the present disclosure, sometimes multiple features are combined into one embodiment, drawings or descriptions thereof. This method of disclosure does not, however, imply that the subject matter of the disclosure requires more features than are recited in the claims. Rather, claimed subject matter may lie in less than all features of a single foregoing disclosed embodiment.

In some embodiments, counts describing the quantity of components and attributes are used. It should be understood that such counts used in the description of the embodiments use the modifiers “about”, “approximately” or “substantially” in some examples. Unless otherwise stated, “about”, “approximately” or “substantially” indicates that the stated figure allows for a variation of ±20%. Accordingly, in some embodiments, the numerical parameters used in the disclosure and claims are approximations that can vary depending upon the desired characteristics of individual embodiments. In some embodiments, numerical parameters should consider the specified significant digits and adopt the general digit retention method. Although the numerical ranges and parameters used in some embodiments of the present disclosure to confirm the breadth of the range are approximations, in specific embodiments, such numerical values are set as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

What is claimed is:

1. A test system for an energy storage management system of a photovoltaic charging pile, comprising an analog unit, a test switch unit, an acquisition unit, and a processor; wherein
the processor is configured to:
generate and execute a first acquisition instruction, the first acquisition instruction being configured to:
obtain a first performance feature set corresponding to a first preset time period by obtaining a plurality of first performance features of an energy storage device of the photovoltaic charging pile during the first preset time period from a battery management system (BMS); wherein the plurality of first performance features correspond to a plurality of photovoltaic power generation efficiencies and/or a plurality of electric vehicle charging modes, the plurality of first performance features are determined based on first sensing data, the first sensing data is sensing data of the energy storage device during the first preset time period; and a charging frequency of the photovoltaic charging pile is greater than a preset frequency during the first preset time period;
in response to determining that the first performance feature set does not satisfy a first preset condition, generate a test start instruction and send the test start instruction to the test switch unit when an external load is null, the test start instruction being configured to enable a test circuit composed of the analog unit and the energy storage device to be conducted through the test switch unit;
in response to determining that the test start instruction is executed and completed, generate a second acquisition instruction and a third acquisition instruction and send the second acquisition instruction and the third acquisition instruction to the BMS and the acquisition unit, respectively, the second acquisition instruction being configured to obtain a first test feature of the test circuit from the BMS, and the third acquisition instruction being configured to enable the acquisition unit to acquire test sensing data of the test circuit; wherein the first test feature is determined based on second sensing data, and the second sensing data is sensing data of the energy storage device during a test process of the test circuit;
determine a second test feature based on the test sensing data;
in response to determining that the first test feature and the second test feature satisfy a second preset condition, generate first warning information, the first warning information including prompt information indicating a potential abnormality of the energy storage device; and
in response to determining that the first test feature and the second test feature do not satisfy the second preset condition, generate second warning information and/or generate an accuracy adjustment instruction and send the accuracy adjustment instruction to the BMS, the second warning information including prompt information indicating a potential abnormality of the BMS.

2. The test system of claim 1, wherein the processor is further configured to:
determine, based on the first performance feature set, a second performance feature set corresponding to a second preset time period, the second preset time period being a future time period; wherein
the first preset condition includes that a count of target performance features is greater than a preset number threshold, the target performance features include first performance features of the first performance feature set of which performance evaluation values are less than a first performance threshold, and second performance features of the second performance feature set of which performance evaluation values are less than a second performance threshold.

3. The test system of claim 2, wherein the processor is further configured to:
determine the second performance feature set by processing the first performance feature set through a performance feature prediction model; the performance feature prediction model being a machine learning model.

4. The test system of claim 3, wherein an input of the performance feature prediction model includes a current set value of a charging control parameter of the photovoltaic charging pile.

5. The test system of claim 4, wherein
the performance feature prediction model is obtained by training based on a plurality of training samples and a plurality of labels corresponding to the plurality of training samples; and
the plurality of training samples correspond to a plurality of learning rates; and
the learning rate corresponding to each of the plurality of training samples is determined based on a ratio of a sample length of each of the plurality of training samples to a label length of each of the plurality of training samples.

6. The test system of claim 2, wherein the second performance threshold is related to a count of the plurality of first performance features in the first performance feature set.

7. The test system of claim 1, wherein the second preset condition includes that a difference between the first test feature and the second test feature is less than a preset difference threshold; and
the processor is further configured to:
in response to determining that the first test feature and the second test feature do not satisfy the second preset condition:
determine a preferred parameter adjustment set, and generate a parameter update instruction based on the preferred parameter adjustment set; and
send the parameter update instruction to the BMS to cause the BMS to update, based on preferred parameter adjustment set, a charging control parameter of the photovoltaic charging pile.

8. The test system of claim 7, wherein the preset difference threshold is related to a performance difference value, and the performance difference value is determined based on a performance evaluation value of the second performance feature set and a performance evaluation value of the first performance feature set.

9. The test system of claim 7, wherein the processor is further configured to:
generate a plurality of candidate parameter adjustment sets;
predict an estimated performance feature set corresponding to each set of the plurality of candidate parameter adjustment sets; and
determine the preferred parameter adjustment set based on the estimated performance feature set.

10. The test system of claim 9, wherein the processor is further configured to:
determine a set generation volume based on the count of the plurality of first performance features in the first performance feature set; and
generate the plurality of candidate parameter adjustment sets based on the set generation volume.

11. The test system of claim 9, wherein the processor is further configured to:
predict a plurality of estimated performance feature sets corresponding to the plurality of candidate parameter adjustment sets by processing the first performance feature set, and an update value of the charging control parameter of the photovoltaic charging pile through a performance feature prediction model; the performance feature prediction model being a machine learning model; wherein
the update value of the charging control parameter of the photovoltaic charging pile is a value obtained by adjusting a current set value of the charging control parameters of the photovoltaic charging pile based on the plurality of candidate parameter adjustment sets.

12. A test method for an energy storage management system of a photovoltaic charging pile, implemented based on a processor, comprising:
generating and executing a first acquisition instruction, the first acquisition instruction being configured to:
obtain a first performance feature set corresponding to a first preset time period by obtaining a plurality of first performance features of an energy storage device of the photovoltaic charging pile during the first preset time period from a battery management system (BMS); wherein the plurality of first performance features correspond to a plurality of photovoltaic power generation efficiencies and/or a plurality of electric vehicle charging modes, the plurality of first performance features are determined based on first sensing data, the first sensing data is sensing data of the energy storage device during the first preset time period; and a charging frequency of the photovoltaic charging pile is greater than a preset frequency during the first preset time period;
in response to determining that the first performance feature set does not satisfy a first preset condition, generate a test start instruction and send the test start instruction to the test switch unit when an external load is null, the test start instruction being configured to enable a test circuit composed of the analog unit and the energy storage device to be conducted through the test switch unit;
in response to determining that the test start instruction is executed and completed, generate a second acquisition instruction and a third acquisition instruction and send the second acquisition instruction and the third acquisition instruction to the BMS and the acquisition unit, respectively, the second acquisition instruction being configured to obtain a first test feature of the test circuit from the BMS, and the third acquisition instruction being configured to enable the acquisition unit to acquire test sensing data of the test circuit; wherein the first test feature is determined based on second sensing data, and the second sensing data is sensing data of the energy storage device during a test process of the test circuit;
determine a second test feature based on the test sensing data;
in response to determining that the first test feature and the second test feature satisfy a second preset condition, generate first warning information, the first warning information including prompt information indicating a potential abnormality of the energy storage device; and
in response to determining that the first test feature and the second test feature do not satisfy the second preset condition, generate second warning information and/or generate an accuracy adjustment instruction and send the accuracy adjustment instruction to the BMS, the second warning information including prompt information indicating a potential abnormality of the BMS.

13. The test method of claim 12, further comprising:
determining, based on the first performance feature set, a second performance feature set corresponding to a second preset time period, the second preset time period being a future time period; wherein
the first preset condition includes that a count of target performance features is greater than a preset number threshold, the target performance features include first performance features of the first performance feature set of which performance evaluation values are less than a first performance threshold, and second performance features of the second performance feature set of which performance evaluation values are less than a second performance threshold.

14. The test method of claim 13, wherein the determining, based on the first performance feature set, a second performance feature set corresponding to a second preset time period includes:
determining the second performance feature set by processing the first performance feature set through a performance feature prediction model; the performance feature prediction model being a machine learning model.

15. The test method of claim 14, wherein an input of the performance feature prediction model includes a current set value of a charging control parameter of the photovoltaic charging pile.

16. The test method of claim 15, wherein
the performance feature prediction model is obtained by training based on a plurality of training samples and a plurality of labels corresponding to the plurality of training samples; and
the plurality of training samples correspond to a plurality of learning rates; and
the learning rate corresponding to each of the plurality of training samples is determined based on a ratio of a sample length of each of the plurality of training samples to a label length of each of the plurality of training samples.

17. The test method of claim 13, wherein the second performance threshold is related to a count of the plurality of first performance features in the first performance feature set.

18. The test method of claim 12, wherein the second preset condition includes that a difference between the first test feature and the second test feature is less than a preset difference threshold; and
the method further comprises:
in response to determining that the first test feature and the second test feature do not satisfy the second preset condition:
determining a preferred parameter adjustment set, and generating a parameter update instruction based on the preferred parameter adjustment set; and
sending the parameter update instruction to the BMS to cause the BMS to update, based on preferred parameter adjustment set, the charging control parameter of the photovoltaic charging pile.

19. The test method of claim 18, wherein the preset difference threshold is related to a performance difference value, and the performance difference value is determined based on a performance evaluation value of the second performance feature set and a performance evaluation value of the first performance feature set.

20. A non-transitory computer readable storage medium, comprising computer instructions that, when read by a computer, direct the computer to implement the test method for the energy storage management system of the photovoltaic charging pile of claim 12.
